(19) United States
(12) Patent Application Publication
(10) Pub. No.: US 2026/0128252 A1
(43) Pub. Date: May 7, 2026

(54) VERTICAL ELECTRODE CONFIGURATION

(71) Applicant: Applied Materials, Inc., Santa Clara, CA (US)

(72) Inventors: KALLOL BERA, San Jose, CA (US); RUPALI SAHU, Milpitas, CA (US); SATHYA SWAROOP GANTA, Sunnyvale, CA (US); SHAHID RAUF, Pleasanton, CA (US)

(21) Appl. No.: 18/940,731

(22) Filed: Nov. 7, 2024

(51) Int. Cl. H01J 37/063; H01J 37/32

(52) U.S. Cl. CPC H01J 37/063; H01J 37/32568; H01J 37/32091

(57) ABSTRACT

Embodiments disclosed herein include electrode configurations for a plasma-enhanced deposition process. In an example, an electrode configuration includes a stack of wafer processing regions aligned along a vertical axis. A plurality of electrodes is surrounding the stack of wafer processing regions. Each one of the plurality of electrodes is extending along the vertical axis.

### FIELD

Embodiments of the present disclosure pertain to the field of semiconductor processing and, in particular, vertical electrode configurations.

### DESCRIPTION OF RELATED ART

Deposition of films on a substrate is an important process in a variety of industries including semiconductor processing, diffusion barrier coatings, and dielectrics. In the semiconductor industry, in particular, miniaturization requires atomic level control of film deposition to produce conformal coatings on high aspect structures. One method for deposition of films with control and conformal deposition is atomic layer deposition (ALD), which employs sequential surface reactions to form layers of a same precise thickness on all parts of a structure. Most ALD processes are based on binary reaction sequences which deposit a binary compound film. Because the surface reactions are sequential, the two gas phase reactants are not in contact, and possible gas phase reactions that may form and deposit particles are limited.

### SUMMARY

Embodiments disclosed herein include electrode configurations for a plasma-enhanced deposition process. The electrode configuration includes a stack of wafer processing regions aligned along a vertical axis. A plurality of electrodes is surrounding the stack of wafer processing regions. Each one of the plurality of electrodes is extending along the vertical axis.

Embodiments disclosed herein include a plasma process chamber including a stack of wafer support pedestals aligned along a vertical axis, each of the wafer support pedestals including a corresponding processing region. A plurality of electrodes is surrounding the stack of wafer processing regions, each one of the plurality of electrodes extending along the vertical axis.

Embodiments disclosed herein include a process chamber including a plurality of vertically stacked ceramic wafer pedestals with corresponding wafer processing regions. The process chamber also includes a plurality of RF electrodes. Each one of the plurality of RF electrodes carries the same potential but is out of phase with an adjacent one of the plurality of electrodes by 45-135 degrees.

### BRIEF DESCRIPTION OF THE DRAWINGS

FIG. 1A is an angled view of a vertical electrode configuration for batch processing, in accordance with an embodiment of the present disclosure.

FIG. 1B is a plan view and associated schematic of a vertical electrode configuration for batch processing, and FIG. 1C is an associated cross-sectional view, in accordance with an embodiment of the present disclosure.

FIG. 1D illustrates non-sinusoidal electrode potentials, in accordance with an embodiment of the present disclosure.

FIGS. 1E and 1F illustrate a top-down view of a chamber and a computational setup, respectively, in accordance with an embodiment of the present disclosure.

FIG. 2 is a schematic of a vertical electrode configuration and associated match circuit, in accordance with an embodiment of the present disclosure.

FIGS. 3A and 3B illustrate top-down views of batch processing chambers with vertical electrodes, in accordance with an embodiment of the present disclosure.

FIGS. 3C and 3D illustrate top-down views of batch processing chambers with vertical electrodes, in accordance with another embodiment of the present disclosure.

FIG. 4 illustrates a schematic top-view diagram of an example multi-chamber processing system according to one or more embodiments of the disclosure.

FIG. 5 illustrates a diagrammatic representation of a machine in the exemplary form of a computer system within which a set of instructions, for causing the machine to perform any one or more of the methodologies described herein, may be executed according to an embodiment.

### DETAILED DESCRIPTION

The disclosed embodiments relate to vertical electrode configurations. In the following description, numerous specific details are set forth, in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

Most film properties cannot meet practical requirements due to lack of continuity, lack of conformality, poor film thickness control, and poor film composition control, such as hydrogen contamination and/or different bonding states of carbon in the film. Traditionally, films formed by chemical vapor deposition (CVD) and physical vapor deposition (PVD) processes are often non-continuous and not conformal. Additionally, the CVD process generally has less thickness control than an ALD process. Thermal atomic layer deposition (ALD) methods typically provide films with higher impurities and higher resistivity. Further, these processes must be performed at relatively high substrate temperatures. There is also a need for optimal process throughput. Accordingly, there is a need for PEALD batch processing chambers for processing a plurality of wafers having superior growth rate and films of higher quality.

In contrast, plasma enhanced atomic layer deposition (PEALD) methods add a plasma exposure. In some PEALD methods, a nitrogen source is provided as a plasma, for example, ammonia plasma. The primary benefit of PEALD methods is the relatively low substrate temperature during processing.

However, current batch process chambers and processes implementing batch process chambers do not include the use of plasma. Inductively coupled plasma (ICP) or remote plasma sources, for example, are sometimes used as an upstream disassociation of chemistry prior to entering a batch process chamber to filter or lower the ion energy. Rather, current PEALD chambers and processes are reserved for single wafer or multi-wafer single process due to complexity (twin or quad or multi-quad processing).

Accordingly, there is a need for PEALD batch processing chambers for processing a plurality of wafers having superior growth rate and films of higher quality.

Embodiments of the disclosure generally relate to batch processing chambers. In particular, embodiments of the disclosure are related to plasma enhanced atomic layer deposition (PEALD) batch processing chambers.

Vertical electrode configurations for batch PEALD are described. Embodiments described herein can be implemented to enable plasma-based processing of multiple wafers simultaneously in a single chamber. Embodiments can include batch plasma enhanced atomic layer deposition, capacitively coupled plasmas, and/or phase-shifter circuits.

To provide context, batch PEALD addresses the need for high quality, high throughput PEALD films. Thermal ALD for dielectric film (e.g., silicon oxide, nitride) can require prohibitively high temperatures. Plasma provides energetic ions and radicals that easily form high quality films at low temperatures. In an embodiment, using a common set of vertical electrodes can ensure uniform plasma characteristics to minimize wafer-to-wafer differences. Additionally, a plasma can be confined above each wafer for efficiency.

To provide further context, compared to batch thermal ALD process, batch PEALD can provide very high throughput with much lower operating temperatures. One of the approaches to batch PEALD is to use a dedicated set of electrodes for each wafer. However, small variations between the different wafer gaps can cause large differences in the respective plasma characteristics. In accordance with one or more embodiments described herein, using a common set of vertically aligned electrodes offers greater uniformity across a wafer and between different wafers.

Embodiments described herein relate to the technology of plasma-based processing of multiple wafers simultaneously in a single chamber. Embodiments can be directed to a device with a configuration that can ensure uniform plasma characteristics over the area of a wafer and minimize wafer-to-wafer differences. Batch processing is currently used for thermal ALD chamber, where uniformity across wafers is regulated by adjusting the flow of gases inside the chamber. Batch thermal ALD offers low throughput due to longer processing and purge times compared to plasma enhanced ALD. Thermal ALD is also limited to very few materials and requires very high temperatures. Due to the impact of ions and radicals generated in plasma, plasma enhanced ALD (PEALD) processes provide high quality films on the wafer. The PEALD process can be performed at lower temperature overcoming the high temperature requirements for thermal ALD. In an embodiment, a configuration described herein is designed as an improvement over the batch thermal ALD process.

In an embodiment, a process chamber has three major components: wafers, ceramic pedestals for the wafers, and RF electrodes. The electrodes carry the same RF potential amplitude but having phase difference with the adjacent electrodes of 30-150 degrees. The number of electrodes and phase-difference between the adjacent electrodes is adjusted so that diametrically opposite electrodes have about 180 degrees phase difference, creating a strong electric field between the two. Process gas is fed from the top and allowed to diffuse uniformly in the chamber, after which the electrodes are powered. The electric field ionizes the process gas, and the resulting ions and radical can be used to deposit atomic layer films on the wafers.

Advantages of using a common set of vertical electrodes for all the wafers can include: (i) ensuring all the process gaps are lighted simultaneously, (ii) all the wafers are exposed to similar levels of plasma processing, (iii) reduce/eliminate damage to the wafer due to ion sputtering and/or (iv) increasing throughput of the generally slow process of ALD. In another aspect, using plasma enhanced ALD for batch processing instead of batch thermal processing assists with (i) lowering the process temperature to accommodate thermal budget, (ii) expanding the ALD process capability to more materials (e.g., SiN, SiO2, etc.) by utilizing a suitable precursor and plasma process at low temperatures, and/or (iii) providing a better film quality due to energetic ions.

Plasma modeling can be used to explore the limitations on batch PEALD. Argon plasma can be used for modeling since Ar is used as a common carrier gas. A 2D simulation of a cross-section for a single wafer is set-up is described below. It was observed that the power required for uniform plasma light-up is a strong function of the process gap and the applied electrode RF potential amplitude. As an example, for a process gap of 12 mm, 7 wafers can be processed simultaneously in a 120 mm tall chamber. Uniform plasma light-up is seen with an input of about 400 W for 1 wafer, which translates to roughly 2.8 KW total power. Similarly, a 16 mm process gap allows for 6 wafers to be processed simultaneously with a total power input of 3.4 KW but offers better uniformity of ion flux to the wafer compared to smaller process gaps. It was also seen that the predicted ion energy for the two cases (12 mm gap and 16 mm gap) is less than 20 eV, whereas it is a few hundred eV when one set of electrode is used for each wafer. Thus, wafer sputtering due to energetic ions can be significantly reduced by using a vertical set of electrodes. Embodiments described herein can be implemented for any plasma enhanced process, especially plasma enhanced atomic layer deposition.

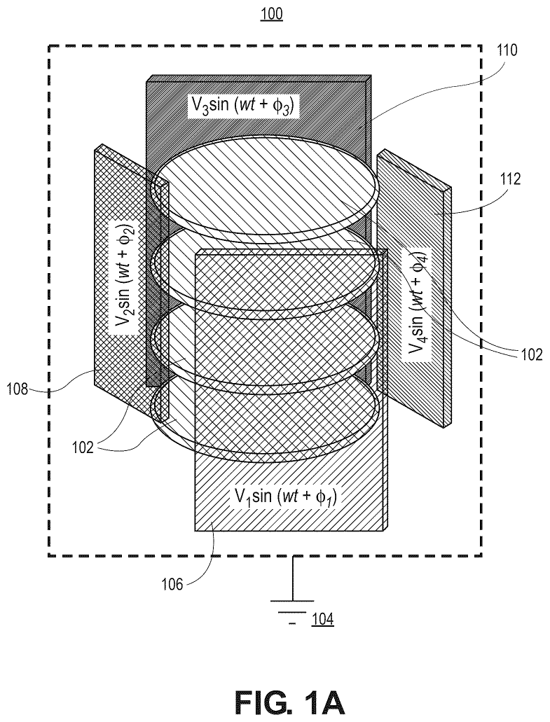

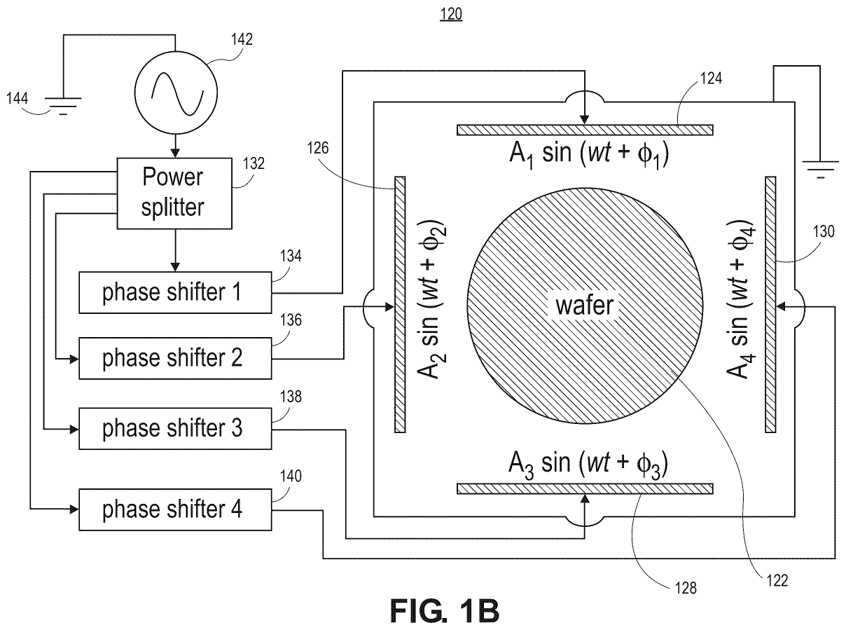

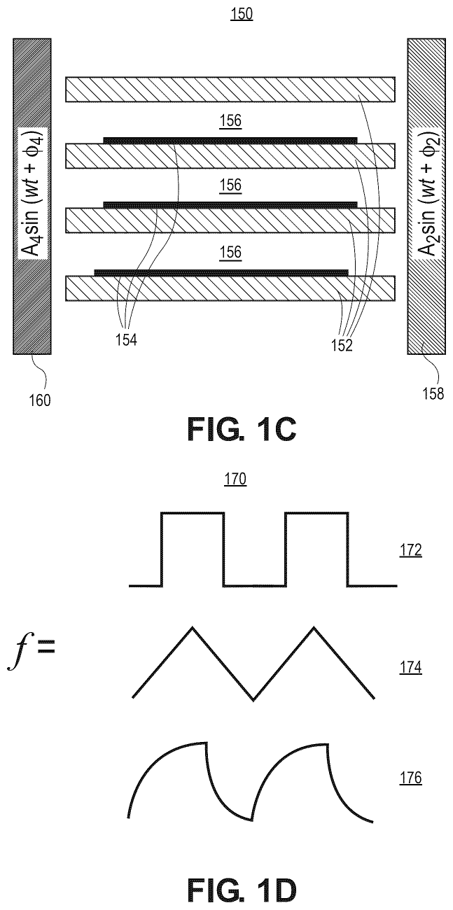

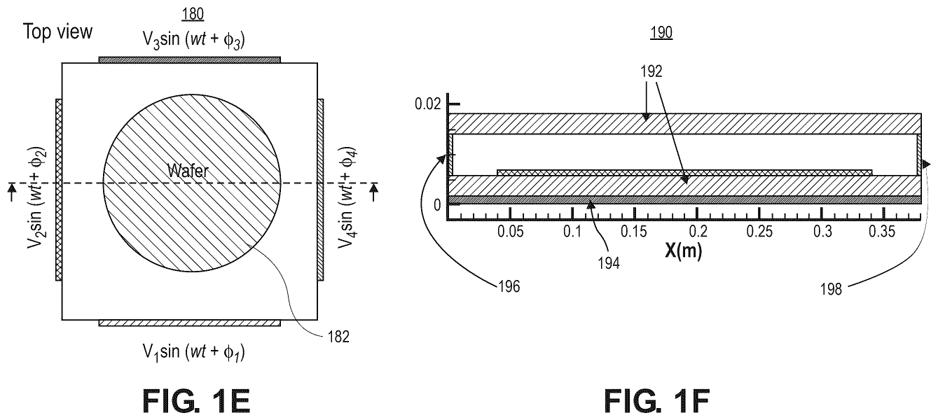

As an exemplary configuration, FIG. 1A is an angled view of a vertical electrode configuration for batch processing, in accordance with an embodiment of the present disclosure.

Referring to FIG. 1A, a processing system 100 includes a stack of wafers 102 (or substrates or workpieces), ground 104, a first vertical electrode 106 (as defined along an axis from a bottom to a top of a stack of wafers), a second vertical electrode 108, a third vertical electrode 110, and a fourth vertical electrode 112.

In reference again to FIG. 1A, in accordance with one or more embodiments, a stack of wafers, each atop dielectric supports, is placed inside the chamber. The number of wafers in the stack depends on the process gap needed for stable and uniform plasma in each gap. A common set of electrodes is used, each 90° out-of-phase with the adjacent ones, so that the opposite electrodes are 180° out-of-phase. Each wafer sees the same electrical environment. Plasma generation between any two electrodes exposes all wafers to plasma with similar characteristics simultaneously, i.e., there is no delay in ignition and sustenance near any electrode overcoming wafer-to-wafer differences.

As an exemplary configuration, FIG. 1B is a plan view and associated schematic of a vertical electrode configuration for batch processing, and FIG. 1C is an associated cross-sectional view, in accordance with an embodiment of the present disclosure.

Referring to FIG. 1B, a processing system 120 includes a stack of wafers 122 (or substrates or workpieces), ground 144, a first vertical electrode 124, a second vertical electrode 126, a third vertical electrode 128, and a fourth vertical electrode 130. A phase shifter 134, 136, 138 or 140 is coupled to a corresponding one of the first vertical electrode 124, the second vertical electrode 126, the third vertical electrode 128, and the fourth vertical electrode 130, respectively. A power splitter 132 is coupled to the phase shifters 134, 136, 138 and 140. A power source 142 is coupled to the power splitter 132 and ground 144.

Referring to FIG. 1C, a cross-sectional view 150 includes dielectric supports 152, wafers 154, and vertical electrodes 158 and 160.

Referring again to FIGS. 1B and 1C, a representative configuration of a design for batch PEALD is described. As shown, there are multiple wafers sitting on dielectric pedestals attached to a chamber body. Four vertical electrodes are used, so that the required phase difference between adjacent electrodes is 90 degrees. The actual number of dielectric pedestals, which determines the number of wafers in the chamber, depends on the process gap 156 (the distance between the wafer and the dielectric directly above it), and the total height of the chamber.

In an embodiment, a vertical electrode configuration provides a harmonic electrode potential. In an embodiment, the phase shifters 134, 136, 138 and 140 can be replaced with time delays to provide a non-sinusoidal electrode potential. As an example of non-sinusoidal electrode potentials, FIG. 1D illustrates non-sinusoidal (non-harmonic) electrode potentials 170, in accordance with an embodiment of the present disclosure. The non-sinusoidal electrode potentials 170 can include pulsed 172, triangular 174, RC/exponential 176, etc., as long as a strong electric field can be established between the electrodes. Here, a time-delay τ is used to manipulate the potential difference between electrodes.

FIGS. 1E and 1F illustrate a top-down view of a chamber and a computational setup, respectively, in accordance with an embodiment of the present disclosure. Referring to FIG. 1E, a chamber 180 includes wafers 182 surrounded by four vertical electrodes. Referring to FIG. 1F, a model 190 can be used to predict the performance of the design of FIG. 1E. The model 190 includes dielectric supports 192, ground 194, and out-of-phase electrodes 196 and 198.

Referring again to FIGS. 1E and 1F, only one wafer domain is simulated, including the supporting dielectric pedestal and the dielectric slab beyond the process gap. Two out-of-phase electrodes establish an electric field along the x-direction. RF potential on the electrodes generates plasma near the electrodes, which diffuses into the process gap. The target is to have a uniform ion/radical flux normal to the exposed surface of the wafer, since it is the ion and radical fluxes that determine surface processes (i.e. deposition/etching, film densification, etc.). A uniform ion flux is a consequence of uniform plasma density over the wafers. The electrode RF potential amplitude and the process gap are varied to find the set of parameters that would provide uniform plasma density in the domain.

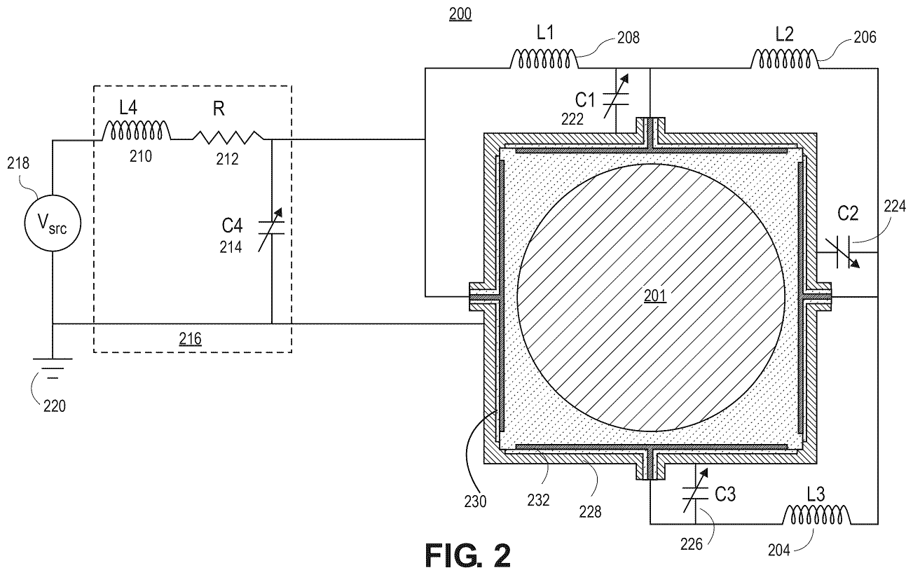

FIG. 2 is a schematic of a vertical electrode configuration and associated match circuit, in accordance with an embodiment of the present disclosure. Referring to FIG. 2, a system 200 includes a stack of wafers 201 within a set of vertical electrodes 232, capacitors 202 and 214, inductors 204, 206, 208 and 210, and a resistor 212. A match circuit 216 is highlighted in the dashed box. A voltage supply 218 is coupled to the match circuit 216 and to ground 220. The process chamber walls 228 are grounded. A dielectric layer 230 is placed between the electrodes 232 and the chamber walls 228. The circuit design which ensures that port impedance for all electrodes is similar and adjacent electrodes are out of phase by 90 degrees. The circuit values are calculated for an input power of 200 W, total input impedance of 50 Ω, match inductance of L can vary between 0.1 to 10 nH and match capacitance can vary from 0.1 to 100 nF or 1 to 10 nF. The resistance R can range from 1 to 100 Ω. The capacitance values of capacitors C1 (222 in FIG. 2), C2 (224 in FIG. 2), and C3 (226 in FIG. 2), can range from 0.1 to 100 nF, or 1 to 10 nF. The inductance of the inductors L1 (208 in FIG. 2), L2 (206 in FIG. 2) and L3 (204 in FIG. 2) range from 0.1 to 100 nH or 1 to 100 nH. A similar port impedance for all electrodes is required to establish similar electrode RF potential amplitude. As an example the circuit value of L=1nH, R=45.3 Ω, C=1 nF, C1=C2=C3=2 nF, L1=18.6 nH, L2=37.2 nH, L3=74.4 nH. The proposed circuit values are well within normal operating ranges for a PEALD chamber.

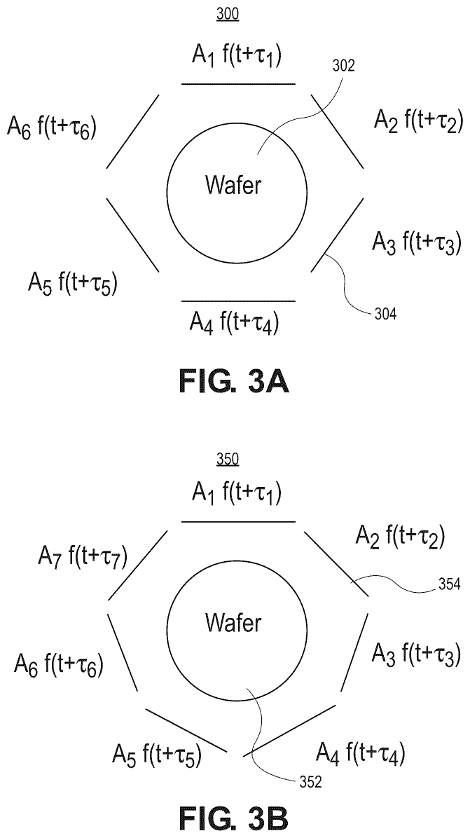

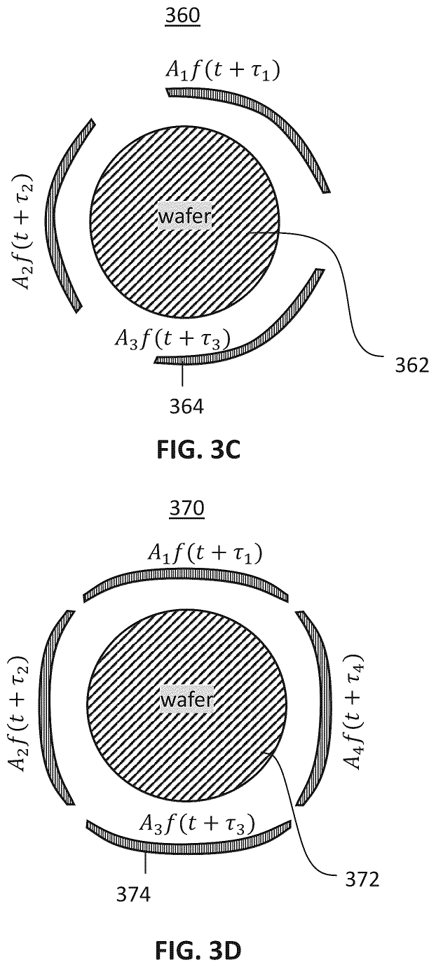

It is to be appreciated that configurations are not limited to four electrodes. As exemplary alternative embodiments, FIGS. 3A and 3B illustrate top-down views of batch processing chambers with vertical electrodes, in accordance with an embodiment of the present disclosure.

Referring to FIG. 3A, a process chamber 300 includes a stack of wafers 302 surrounded by six vertical electrodes 304. Referring to FIG. 3B, a process chamber 350 includes a stack of wafers 352 surrounded by seven vertical electrodes 354. In either case, in an embodiment, a time-delay τ can be used between adjacent electrodes to create a potential difference and consequently desired electric field between the electrodes.

Referring to FIG. 3C, process chamber 360 has a stack of wafers 362 surrounded by a set of three electrodes 364. The electrodes 364 are shaped to have a curvature in the plane of the wafer, and are straight along the vertical axis. Shaping the electrodes can improve the uniformity of electric field seen by the wafer, hence increasing process uniformity. It can also allow for better gas flow distribution. Referring to FIG. 3D, process chamber 370 has a wafer stack 372 surrounded by 4 electrodes 374 which are shaped in the plane of the wafer, and are straight along the vertical axis.

Described herein is an embodiment of a method wherein a deposited film is formed on the surface of a substrate in the processing chamber 100, 120, 150, 180, 190, 200, 300 or 350 using an atomic layer deposition (ALD) process. The processing chamber 100, 120, 150, 180, 190, 200, 300 or 350 is configured to perform PEALD of metal nitrides, metal oxides or dielectric such as aluminum oxide (Al2O3), silicon oxide (SiO2), silicon nitride (SiN), and titanium oxide (TiO2). Embodiments of the disclosure are advantageously directed to treating an ALD-formed film in a process chamber, such as the PICOSUN® Sprinter ALD system. Embodiments of the disclosure are advantageously directed to treating an ALD-formed film with a plasma in a batch process chamber 100, 120, 150, 180, 190, 200, 300 or 350. The plasma may be generated from one or more remote plasma sources, ICP coils, and/or RF power sources as described herein. Methods described herein is exemplary and should not be construed as limiting. The methods of the disclosure may contain additional process operations to those described herein.

Each process gas may be supplied under different parameters than other process gasses. A process gas may be provided in one or more pulses or continuously. The flow rate of a process gas can be any suitable flow rate including, but not limited to, flow rates is in the range of about 1 to about 5000 sccm, or in the range of about 2 to about 4000 sccm, or in the range of about 3 to about 3000 sccm or in the range of about 5 to about 2000 sccm. A process gas can be provided at any suitable pressure including, but not limited to, a pressure in the range of about 5 mTorr to about 25 Torr, or in the range of about 100 mTorr to about 20 Torr, or in the range of about 5 Torr to about 20 Torr, or in the range of about 50 mTorr to about 2000 mTorr, or in the range of about 100 mTorr to about 1000 mTorr, or in the range of about 200 mTorr to about 500 mTorr.

The period of time that the substrate is exposed to a process gas may be any suitable amount of time necessary to allow the formation of an adequate nucleation layer or reaction atop the substrate surface. For example, a process gas may be flowed into the process chamber for a period of about 0.1 seconds to about 90 seconds. In some time-domain ALD processes, a process gas is exposed the substrate surface for a time in the range of about 0.1 sec to about 90 sec, or in the range of about 0.5 sec to about 60 sec, or in the range of about 1 sec to about 30 sec, or in the range of about 2 sec to about 25 sec, or in the range of about 3 sec to about 20 sec, or in the range of about 4 sec to about 15 sec, or in the range of about 5 sec to about 10 sec.

In some embodiments, an inert gas may additionally be provided to the process chamber at the same time as a process gas. The inert gas may be mixed with a process gas (e.g., as a diluent gas) or separately and can be pulsed or of a constant flow. In some embodiments, the inert gas is flowed into the processing chamber at a constant flow in the range of about 1 to about 10000 sccm. The inert gas may be any inert gas, for example, such as argon, helium, neon, combinations thereof, or the like.

The temperature of the substrate during deposition can be controlled, for example, by setting the temperature of the substrate support or susceptor. In some embodiments the substrate is held at a temperature in the range of about 100 ° C. to about 600 ° C., or in the range of about 200 ° C. to about 525 ° C., or in the range of about 300° C. to about 475° C., or in the range of about 350° C. to about 450° C. In one or more embodiments, the substrate is maintained at a temperature less than about 475° C., or less than about 450° C., or less than about 425° C., or less than about 400° C., or less than about 375° C.

In addition to the foregoing, additional process parameters may be regulated while exposing the substrate to a process gas. For example, in some embodiments, the process chamber may be maintained at a pressure of about 0.2 to about 100 Torr, or in the range of about 0.3 to about 90 Torr, or in the range of about 0.5 to about 80 Torr, or in the range of about 1 to about 50 Torr.

After exposing the substrate to one process gas, the process chamber 100, 120, 150, 180, 190, 200, 300 or 350 (especially in time-domain ALD) may be purged using an inert gas. (This may not be needed in spatial ALD processes as there is a gas curtain separating the reactive gases.) The inert gas may be any inert gas, for example, such as argon, helium, neon, or the like. In some embodiments, the inert gas may be the same, or alternatively, may be different from the inert gas provided to the process chamber during the exposure of the substrate to the first process gas. In embodiments where the inert gas is the same, the purge may be performed by diverting the first process gas from the process chamber, allowing the inert gas to flow through the process chamber, purging the process chamber of any excess first process gas components or reaction byproducts. In some embodiments, the inert gas may be provided at the same flow rate used in conjunction with the first process gas, described above, or in some embodiments, the flow rate may be increased or decreased. For example, in some embodiments, the inert gas may be provided to the process chamber at a flow rate of greater than 0 to about 10000 sccm to purge the process chamber.

The flow of inert gas may facilitate removing any excess process gases and/or excess reaction byproducts from the process chamber to prevent unwanted gas phase reactions. For example, the flow of inert gas may remove excess process gas from the process chamber, preventing a reaction between the first process gas and a subsequent process gas.

The substrate is then exposed to a second process gas for a second period of time. The second process gas may react with the species on the substrate surface to create a deposited film. The second process gas may be supplied to the substrate surface at a flow rate greater than the first process gas. In one or more embodiments, the flow rate is greater than about 1 time that of the first process gas, or about 100 times that of the first process gas, or in the range of about 3000 to 5000 times that of the first process gas. The second process gas can be supplied, in time-domain ALD, for a time in the range of about 1 sec to about 30 sec, or in the range of about 5 sec to about 20 sec, or in the range of about 10 sec to about 15 sec. The second process gas can be supplied at a pressure in the range of about 1 Torr to about 30 Torr, or in the range of about 5 Torr to about 25 Torr, or in the range of about 10 Torr to about 20 Torr, or up to about 50 Torr. The substrate temperature can be maintained at any suitable temperature. In one or more embodiments, the substrate is maintained at a temperature less than about 475° C., or at a temperature about the same as that of the substrate during exposure to the first process gas.

The process chamber may again be purged using an inert gas. The inert gas may be any inert gas, for example, such as argon, helium, neon, or the like. In some embodiments, the inert gas may be the same, or alternatively, may be different from the inert gas provided to the process chamber during previous process operations. In embodiments where the inert gas is the same, the purge may be performed by diverting the second process gas from the process chamber, allowing the inert gas to flow through the process chamber, purging the process chamber of any excess second process gas components or reaction byproducts. In some embodiments, the inert gas may be provided at the same flow rate used in conjunction with the second process gas, described above, or in some embodiments, the flow rate may be increased or decreased. For example, in some embodiments, the inert gas may be provided to the process chamber at a flow rate of greater than 0 to about 10,000 sccm to purge the process chamber.

While the embodiment of the processing method described above includes only two pulses of reactive gases, it will be understood that this is merely exemplary and that additional pulses of process gases may be used. The pulses can be repeated in their entirety or in part. The cycle can be repeated to form a film of a predetermined thickness.

In an embodiment, a workpiece may include any substrate that is commonly used in semiconductor manufacturing environments. For example, the workpiece may include a semiconductor wafer. In an embodiment, semiconductor materials may include, but are not limited to, silicon or III-V semiconductor materials. The semiconductor wafer may be a semiconductor-on-insulator (SOI) substrate in some embodiments. Typically, semiconductor wafers have standard dimensions, (e.g., 200 mm, 300 mm, 450 mm, or even larger, and may be circular, square or rectangular). However, it is to be appreciated that the workpiece may have any dimension. Embodiments may also include workpieces that include non-semiconductor materials, such as glass or ceramic materials. In an embodiment, the workpiece may include circuitry or other structures manufactured using semiconductor processing equipment. In yet another embodiment, the workpiece may include a reticle or other lithography mask object.

In another aspect, plasma processing systems are described.

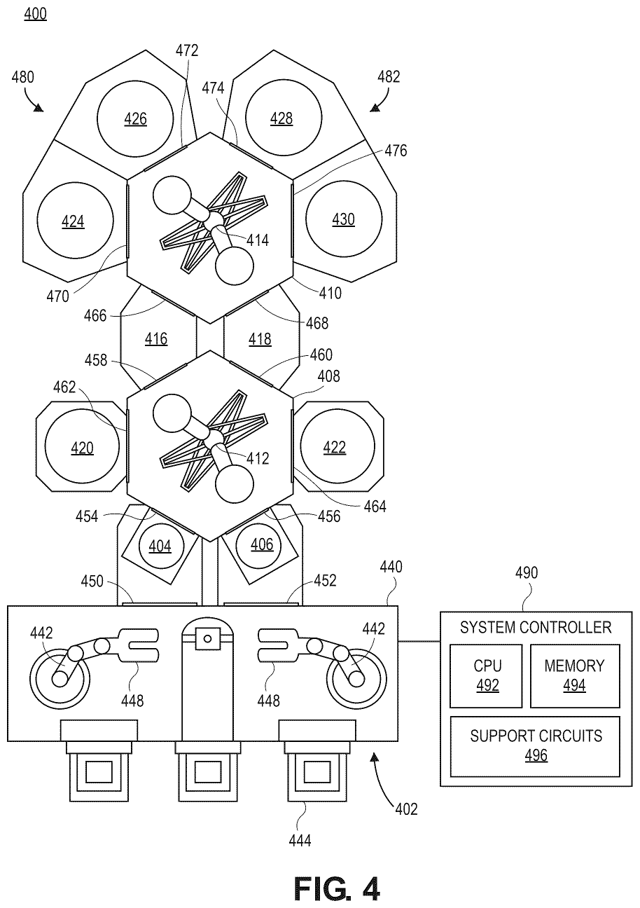

FIG. 4 illustrates a schematic top-view diagram of a multi-chamber processing system 400 according to embodiments of the present disclosure. The processing system 400 generally includes a factory interface 402, load lock chambers 404, 406, transfer chambers 408, 410 with respective transfer robots 412, 414, holding chambers 416, 418, and processing chambers 420, 422, 424, 426, 428, 430. As detailed herein, wafers in the processing system 400 can be processed in and transferred between the various chambers without exposing the wafers to an ambient environment exterior to the processing system 400 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 400. Accordingly, the processing system 400 may provide an integrated solution for some processing of a plurality of wafers.

Embodiments of the present disclosure are directed to single or batch processing chambers including one or more plasma sources. The batch processing chambers described herein may include any suitable plasma source known to the skilled artisan. In some embodiments, the wafer processing region in the processing chamber (e.g., processing chamber 100, 120, 150, 180, 190, 200, 300 or 350) has one or more plasma sources configured to expose each of the plurality of alternating platforms in the wafer cassette to a remote plasma according to one or more embodiments of the disclosure.

Examples of a processing system that may be suitably modified in accordance with the teachings provided herein include the PICOSUN® Sprinter ALD system, the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 4, the factory interface 402 includes a docking station 440 and factory interface robots 442 to facilitate transfer of wafers. The docking station 440 is configured to accept one or more front opening unified pods (FOUPs) 444. In some examples, each factory interface robot 442 generally includes a blade 448 disposed on one end of the respective factory interface robot 442 configured to transfer the wafers from the factory interface 402 to the load lock chambers 404, 406.

The load lock chambers 404, 406 have respective ports 450, 452 coupled to the factory interface 402 and respective ports 454, 456 coupled to the transfer chamber 408. The transfer chamber 408 further has respective ports 458, 460 coupled to the holding chambers 416, 418 and respective ports 462, 464 coupled to processing chambers 420, 422. Similarly, the transfer chamber 410 has respective ports 466, 468 coupled to the holding chambers 416, 418 and respective ports 470, 472, 474, 476 coupled to processing chambers 424, 426, 428, 430. The ports 454, 456, 458, 460, 462, 464, 466, 468, 470, 472, 474, 476 can be, for example, slit valve openings with slit valves for passing wafers therethrough by the transfer robots 412, 414 and for providing a seal between respective chambers to prevent a gas from passing between the respective chambers. Generally, any port is open for transferring a wafer therethrough. Otherwise, the port is closed.

The load lock chambers 404, 406, transfer chambers 408, 410, holding chambers 416, 418, and processing chambers 420, 422, 424, 426, 428, 430 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 444 through a port 450 or 452 to a load lock chamber 404 or 406. The gas and pressure control system then pumps down the load lock chamber 404 or 406. The gas and pressure control system further maintains the transfer chambers 408, 410 and holding chambers 416, 418 with an interior low pressure or vacuum environment (which may include an inert gas). Hence, the pumping down of the load lock chamber 404 or 406 facilitates passing the wafer between, for example, the atmospheric environment of the factory interface 402 and the low pressure or vacuum environment of the transfer chamber 408.

With the wafer in the load lock chamber 404 or 406 that has been pumped down, the transfer robot 412 transfers the wafer from the load lock chamber 404 or 406 into the transfer chamber 408 through the port 454 or 456. The transfer robot 412 is then capable of transferring the wafer to and/or between any of the processing chambers 420, 422 through the respective ports 462, 464 for processing and the holding chambers 416, 418 through the respective ports 458, 460 for holding to await further transfer. Similarly, the transfer robot 414 is capable of accessing the wafer in the holding chamber 416 or 418 through the port 466 or 468 and is capable of transferring the wafer to and/or between any of the processing chambers 424, 426, 428, 430 through the respective ports 470, 472, 474, 476 for processing and the holding chambers 416, 418 through the respective ports 466, 468 for holding to await further transfer. The transfer and holding of the wafer within and among the various chambers can be in the low pressure or vacuum environment provided by the gas and pressure control system.

The processing chambers 420, 422, 424, 426, 428, 430 can be any appropriate chamber for processing a wafer. In some embodiments, the processing chamber 420 can be capable of performing an annealing process, the processing chamber 422 can be capable of performing a cleaning process, and the processing chambers 424, 426, 428, 430 can be capable of performing epitaxial growth processes. In some examples, the processing chamber 422 can be capable of performing a cleaning process, the processing chamber 420 can be capable of performing an etch process, and the processing chambers 424, 426, 428, 430 can be capable of performing respective epitaxial growth processes. The processing chamber 422 may be a SiCoNi™ Preclean chamber available from Applied Materials of Santa Clara, Calif. The processing chamber 420 may be a Selectra™ Etch chamber available from Applied Materials of Santa Clara, Calif.

A system controller 490 is coupled to the processing system 400 for controlling the processing system 400 or components thereof. For example, the system controller 490 may control the operation of the processing system 400 using a direct control of the chambers 404, 406, 408, 416, 418, 410, 420, 422, 424, 426, 428, 430 of the processing system 400 or by controlling controllers associated with the chambers 404, 406, 408, 416, 418, 410, 420, 422, 424, 426, 428, 430. In operation, the system controller 490 enables data collection and feedback from the respective chambers to coordinate performance of the processing system 400.

The system controller 490 generally includes a central processing unit (CPU) 492, memory 494, and support circuits 496. The CPU 492 may be one of any form of a general-purpose processor that can be used in an industrial setting. The memory 494, or non-transitory computer-readable medium, is accessible by the CPU 492 and may be one or more of memory such as random-access memory (RAM), read only memory (ROM), floppy disk, hard disk, or any other form of digital storage, local or remote. The support circuits 496 are coupled to the CPU 492 and may include cache, clock circuits, input/output subsystems, power supplies, and the like. The various methods disclosed herein may generally be implemented under the control of the CPU 492 by the CPU 492 executing computer instruction code stored in the memory 494 (or in memory of a particular process chamber) as, for example, a software routine. When the computer instruction code is executed by the CPU 492, the CPU 492 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 408, 410 and the holding chambers 416, 418. In other examples, more or fewer transfer chambers (e.g., one transfer chamber) and/or more or fewer holding chambers (e.g., no holding chambers) may be implemented as a transfer apparatus in a processing system.

A plasma processing system or the plasma chamber may inject a variety of process gases. Exemplary process gases may include the following: i) dielectric or conductor etch gases including one or more of CF4, C2F6, CHF3, C4F8, C4F6, C3F6, CH2F2, C3H2F4, NF3, SF6, Cl2, HBr; ii) deposition gases including one or more of CH4, C2H2, CH3F; iii) additional gases for co-flow for either etch or deposition including one or more of Ar, N2, O2, He, Kr, Xe, COS; iv) semiconductor material etch deposition gases including one or more of SiCl4, SiCH2Cl2; v) hydride-based deposition gases including one or more of BH3, AlH3, GaH3, NH3; vi) oxide material etch deposition gases including one or more of SiCl4, SiCH2Cl2, and O2; and vii) annealing gases including one or more of NH3, N2, Ar.

In some embodiments, a plasma processing system or a plasma treatment chamber may further include sensors and systems to monitor process chamber conditions including gas flow, velocity, pressure, temperature and the like, with high sensitivities and real time measurement. Particular embodiments can include capacitive wall sensors, on-chip or off-chip thermal sensors, pressure sensors, and/or integrated sensors (capacitive sensors and thermal sensors) on substrates such as ceramic substrate or glass or silicon or flexible substrates. In some embodiments, the sensors can be distributed throughout the chamber to monitor the chamber conditions at various locations, which then can be correlated to overall process performances such as etch rate, etch non-uniformity, particle generation, process drifting, pressure uniformity, etc. In one embodiment, a plurality or an array of pressure sensors can be distributed throughout the chamber to provide data regarding gas flow (e.g., rotation rates, uniformity, velocity) during processing.

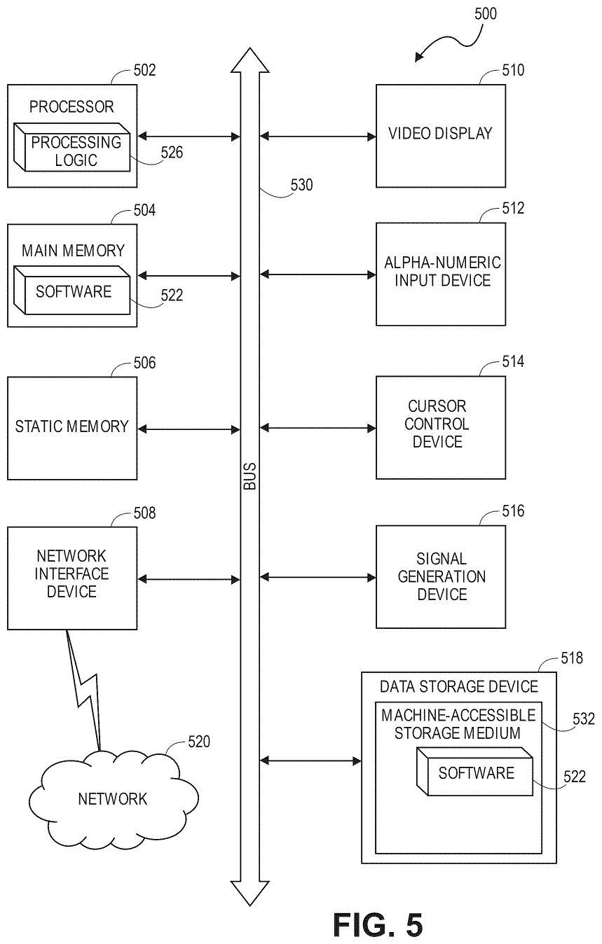

FIG. 5 illustrates a diagrammatic representation of a machine in the exemplary form of a computer system 500 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein. The computer system may be coupled to, e.g., a vertical electrode configuration 100, 120, 150, 180, 190, 200, 300 or 350, the plasma processing system 400, for example.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), MRAM, etc.), and a secondary memory 518 (e.g., a data storage device), which communicate with each other via a bus 530.

Processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 502 may also be one or more special-purpose processing devices such as an application specific integrated circuit (ASIC), a field programmable gate array (FPGA), a digital signal processor (DSP), network processor, or the like. Processor 502 is configured to execute the processing logic 526 for performing the operations described herein.

The computer system 500 may further include a network interface device 508. The computer system 500 also may include a video display unit 510 (e.g., a liquid crystal display (LCD), a light emitting diode display (LED), or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 532 on which is stored one or more sets of instructions (e.g., software 522) embodying any one or more of the methodologies or functions described herein. The software 522 may also reside, completely or at least partially, within the main memory 504 and/or within the processor 502 during execution thereof by the computer system 500, the main memory 504 and the processor 502 also constituting machine-readable storage media. The software 522 may further be transmitted or received over a network 520 via the network interface device 508.

While the machine-accessible storage medium 532 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

Embodiments of plasma excitation methods, apparatuses and processes based on or using a vertical electrode configuration have been disclosed.

What is claimed is:

1. An electrode configuration for a plasma-enhanced deposition process comprising:
a stack of wafer processing regions aligned along a vertical axis; and
a plurality of electrodes surrounding the stack of wafer processing regions, each one of the plurality of electrodes extending along the vertical axis.

2. The plasma source of claim 1, wherein each of the plurality of electrodes has the same RF potential amplitude.

3. The plasma source of claim 2, wherein each one of the plurality of electrodes have phase difference of 30-150 degrees with respect to an adjacent one of the plurality of electrodes.

4. The plasma source of claim 1, wherein the plurality of electrodes has a non-sinusoidal electrode potential.

5. The plasma source of claim 4, wherein each one of the plurality of electrodes is time delayed with respect to an adjacent one of the plurality of electrodes.

6. The plasma source of claim 1, wherein the plurality of electrodes comprises at least three electrodes, each shaped to have curvature in the wafer plane.

7. The plasma source of claim 1, wherein the plurality of electrodes comprises at least four electrodes.

8. The plasma source of claim 7, wherein the plurality of electrodes comprises five, or more electrodes.

9. A plasma process chamber, comprising:
a stack of wafer support pedestals aligned along a vertical axis, each of the wafer support pedestals comprising a corresponding processing region; and
a plurality of electrodes surrounding the stack of wafer processing regions, each one of the plurality of electrodes extending along the vertical axis.

10. The plasma process chamber of claim 9, wherein each of the plurality of electrodes has the same RF potential amplitude.

11. The plasma process chamber of claim 10, wherein each one of the plurality of electrodes has phase difference of 30-150 degrees with respect to an adjacent one of the plurality of electrodes.

12. The plasma process chamber of claim 10, wherein each one of the plurality of electrodes is time delayed with respect to an adjacent one of the plurality of electrodes.

13. The plasma process chamber of claim 9, wherein the plurality of electrodes has a non-sinusoidal electrode potential.

14. The plasma process chamber of claim 9, wherein the plurality of electrodes comprises exactly three electrodes.

15. The plasma process chamber of claim 9, wherein the plurality of electrodes comprises at least four electrodes.

16. The plasma process chamber of claim 15, wherein the plurality of electrodes comprises five electrodes, six electrodes or more electrodes.

17. A process chamber, comprising:
a plurality of vertically stacked ceramic wafer pedestals; and
a plurality of RF electrodes, wherein each one of the plurality of RF electrodes carries the same RF potential amplitude but has phase difference with an adjacent one of the plurality of electrodes of 30-150 degrees.

18. The process chamber of claim 17, wherein the number of electrodes and phase-difference between the adjacent electrodes is adjusted so that diametrically opposite electrodes have about 180 degrees phase difference.

19. The process chamber of claim 17, wherein the plurality of electrodes comprises at least three electrodes.

20. The process chamber of claim 19, wherein each one of the plurality of RF electrodes has a phase difference with an adjacent one of the plurality of electrodes of 30-150 degrees.
